(19) United States
(12) Patent Application Publication
(10) Pub. No.: US 2016/0088758 A1
(43) Pub. Date: Mar. 24, 2016

(54) FASTENING APPARATUS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YONG-ZHAO HUANG, Wuhan (CN); GUANG-FENG OU, Wuhan (CN)

(21) Appl. No.: 14/584,615

(22) Filed: Dec. 29, 2014

(30) Foreign Application Priority Data
Sep. 22, 2014 (CN) 201410484764.2

(51) Int. Cl. H05K 7/14; F16M 13/02

(52) U.S. Cl. CPC H05K 7/1417; F16M 13/02

(57) ABSTRACT

A fastening apparatus for fixing a circuit board includes a bracket. The bracket includes a main plate, two extending plates extending perpendicularly from opposite ends of the main plate, two fixing tabs extending perpendicularly from distal ends of the two extending plates, and two fastening tabs. The main plate and the two extending plates clamp the circuit board, and the two fastening tabs couple the circuit board to the bracket.

### FIELD

The subject matter herein generally relates to a fastening apparatus for a circuit board.

### BACKGROUND

In general, a circuit board is fixed to a chassis by screws. However, traces near edges of the circuit board can cause electromagnetic radiation.

### BRIEF DESCRIPTION OF THE DRAWINGS

Implementations of the present technology will now be described, by way of example only, with reference to the attached figures.

FIG. 1 is an exploded, isometric view of an embodiment of a fastening apparatus, a chassis, and a circuit board.

FIG. 2 is an assembled, isometric view of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

The present disclosure is in relation to a chassis with a circuit board fastening apparatus.

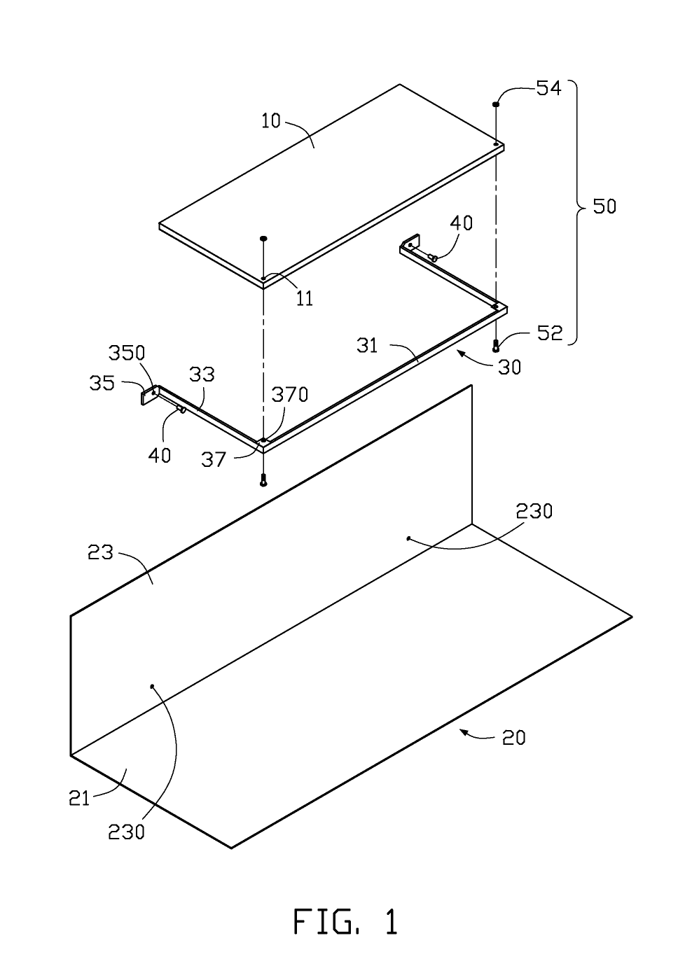

FIG. 1 illustrates an exemplary embodiment of a fastening apparatus. The fastening apparatus is used to fix a circuit board 10 to a chassis 20 of an electronic device. The fastening apparatus comprises a bracket 30, a pair of fixing members 50, and a plurality of fasteners 40. The circuit board 10 defines two through holes 11 in two corners. In the embodiment, the fasteners 40 are screws. Each fixing member 50 comprises a screw 52 and a nut 54

The chassis 20 comprises a base board 21, and a side board 23 extending perpendicularly from a side of the base board 21. The side board 23 defines two horizontally aligned fastening holes 230 adjacent to the base board 21. In the embodiment, the fastening holes 230 are screw holes.

The bracket 30 comprises a main plate 31, two extending plates 33 extending perpendicularly from opposite ends of the main plate 31, and two fixing tabs 35 extending outwardly and perpendicularly from distal ends of the two extending plates 33. Two fastening tabs 37 are formed at joints between the main plate 31 and the two extending plates 33, respectively. Each fixing tab 35 defines a through hole 350. Each fastening tab 37 defines a through hole 370. In the embodiment, the bracket 30 is integrally made of metal materials.

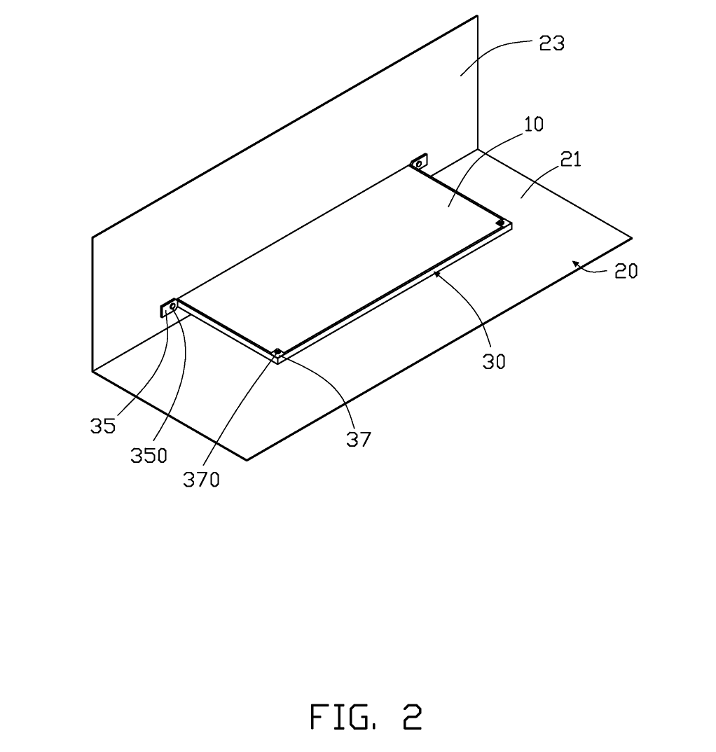

FIG. 2 illustrates an assembly of the circuit board 10, the chassis 20, and the fastening apparatus. To attach the circuit board 10 to the bracket 30, the circuit board 10 is located between the two extending plates 33 of the bracket 30. The circuit board 10 abuts against inside surfaces of the two extending plates 33 and the main plate 31, and the through holes 11 of the circuit board 10 are aligned with the through holes 370 of the two fastening tabs 37. The screws 52 extend through the through holes 370 and the through holes 11 to engage with the nuts 54.

To attach the bracket 30 and the circuit board 10 to the chassis 20, the fixing tabs 35 of the bracket 30 abut against an inside surface of the side board 23, and the through holes 350 of the two fixing tabs 35 are aligned with the fastening holes 230 of the side board 23. Two fasteners 40 extend through the through holes 350 to engage in the fastening holes 230, the bracket 30 is thereby fixed to the chassis 20.

The bracket 30 is made of metal materials and surrounds the circuit board 10, which can suppress electromagnetic radiations (EMR).

The embodiments shown and described above are only examples. Many details are often found in the art such as the other features of a fastening apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A fastening apparatus for fixing a circuit board comprising:
a bracket made of metal materials and comprising a main plate, two extending plates extending perpendicularly from opposite ends of the main plate, and two fixing tabs extending perpendicularly from distal ends of the two extending plates;
wherein the main plate and the two extending plates clamp the circuit board therebetween.

2. The fastening apparatus of claim 1, wherein two fastening tabs are formed at joints between the main plate and the two extending plate respectively, a pair of fixing members respectively extends through the fastening tabs to couple the circuit board to the bracket.

3. The fastening apparatus of claim 2, wherein each fixing member comprises a screw and a nut, each fastening tab defines a through hole, the circuit board defines two through holes, the two screws extend through the through holes of the fastening tabs and the two through holes of the circuit board to engage in the two nuts.

4. An electronic device comprising:
a circuit board;
a chassis comprising a base board and a side board extending from the base board;
a bracket made of metal materials and comprising a main plate, two extending plates extending perpendicularly from opposite ends of the main plate, and two fixing tabs extending perpendicularly from distal ends of the two extending plates;
a pair of fasteners;
wherein the main plate and the two extending plates clamps the circuit board therebetween and the fasteners extend through the fixing tabs to engage with the side board to couple the circuit board to the chassis.

5. The electronic device of claim 4, wherein two fastening tabs are formed at joints between the main plate and the two extending plate respectively, a pair of fixing members respectively extends through the fastening tabs to fix the circuit board to the bracket.

6. The electronic device of claim 5, wherein each fixing member comprises a screw and a nut, each fastening tab defines a through hole, the circuit board defines two through holes, the two screws extend through the through holes of the fastening tabs and the two through holes of the circuit board to engage in the two nuts.
